(19) United States
(12) Patent Application Publication
(10) Pub. No.: US 2019/0338783 A1
(43) Pub. Date: Nov. 7, 2019

(54) DUAL-IMPELLER DRIVING DEVICE AND LIQUID-COOLING HEAT DISSIPATION DEVICE WITH SAME

(71) Applicant: AURAS Technology Co., Ltd., New Taipei City (TW)

(72) Inventors: Mu-Shu Fan, New Taipei City (TW); Che-Chia Chang, New Taipei City (TW); Chien-Yu Chen, New Taipei City (TW)

(21) Appl. No.: 16/011,693

(22) Filed: Jun. 19, 2018

(30) Foreign Application Priority Data
May 4, 2018 (TW) 107115276

(51) Int. Cl. F04D 29/38; F28D 1/047; F28D 1/02; H05K 7/20; F04D 25/06; F04D 29/058; F04D 29/054

(52) U.S. Cl. CPC F04D 29/384; F28D 1/0477; F28D 1/024; F28D 2021/0031; F04D 25/0646; F04D 29/058; F04D 29/054; H05K 7/20272

(57) ABSTRACT

A dual-impeller driving device and a liquid-cooling heat dissipation device with the dual-impeller driving device are provided. The dual-impeller driving device includes a double-sided circuit board, a first stator, a first magnetic element, a first impeller, a second stator, a second magnetic element, a second impeller and a shaft. The first stator is located beside a first active surface of the double-sided circuit board. The first magnetic element is located near the first stator. The first impeller is combined with the first magnetic element. The second stator is located beside a second active surface of the double-sided circuit board. The second magnetic element is located near the second stator. The second impeller is combined with the second magnetic element. The shaft is penetrated through the double-sided circuit board. The first impeller and the second impeller are rotated about the shaft.

### FIELD OF THE INVENTION

The present invention relates to a liquid-cooling heat dissipation technology, and more particularly to a dual-impeller driving device and a liquid-cooling heat dissipation device with the dual-impeller driving device.

### BACKGROUND OF THE INVENTION

A liquid-cooling heat dissipation device is one of the widely-used heat dissipation devices. Generally, a liquid-cooling heat dissipation device comprises a liquid-cooling head, a liquid-cooling radiator and a pump. After the liquid-cooling head, the liquid-cooling radiator and the liquid pump are connected with each other through communication pipes or directly connected with each other, a circular loop is defined. In addition, a working fluid is filled in the circular loop. After the heat from a heat source is absorbed by the working fluid within the liquid-cooling head, the working fluid is transferred to the liquid-cooling radiator. Then, the temperature of the working fluid is decreased through plural fins and a fan. After the working fluid is cooled, the working fluid is returned back to the liquid-cooling head. Consequently, the working fluid can be circulated along a next loop. The pump is installed in the circular loop. By the pump, the working fluid can be well transferred along the circular loop.

Generally, the fan and the pump are independent components. For reducing the volume of the liquid-cooling heat dissipation device and reducing the number of the control circuits, U.S. Pat. No. 6,827,131 discloses a design of integrating a fan with a pump. However, the impeller of the fan is larger and the impeller of the pump is smaller, and the required rotating speeds of the fan and the pump are different. If the impeller of the fan and the impeller of the pump are coaxially and synchronously driven by the same motor, the operations of these two components are interfered with each other. Under this circumstance, the functions of the fan and the pump cannot be normally provided. In other words, the coaxial structure of the fan and the pump needs to be further improved.

### SUMMARY OF THE INVENTION

For solving the drawbacks of the conventional technologies, the present invention provides a dual-impeller driving device and a liquid-cooling heat dissipation device with the dual-impeller driving device. Since two impellers are coaxially driven, the volume of the liquid-cooling heat dissipation device is reduced. Since the two impellers are independently controlled, the fan and the pump are independently operated. In other words, the operations of the two components are not interfered with and influenced by each other.

In accordance with an aspect of the present invention, there is provided a dual-impeller driving device. The dual-impeller driving device includes a double-sided circuit board, a first stator, a first magnetic element, a first impeller, a second stator, a second magnetic element, a second impeller and a shaft. The double-sided circuit board has a first active surface and a second active surface. The first active surface and the second active surface are opposed to each other. The first stator is located beside the first active surface. The first magnetic element is located near the first stator. The first impeller is combined with the first magnetic element. The second stator is located beside the second active surface. The second magnetic element is located near the second stator. The second impeller is combined with the second magnetic element. The shaft is penetrated through the double-sided circuit board. The first impeller and the second impeller are rotated about the shaft.

In an embodiment, the first active surface of the double-sided circuit board, the first stator and the first magnetic element interact with each other to drive a rotation of the first impeller, and the second active surface of the double-sided circuit board, the second stator and the second magnetic element interact with each other to drive a rotation of the second impeller.

In an embodiment, a rotation of the first impeller and a rotation of the second impeller are independent from each other and not linked with each other.

In an embodiment, the dual-impeller driving device further includes a casing, and the double-sided circuit board, the first stator and the second stator are enclosed by the casing.

In an embodiment, the dual-impeller driving device further includes a casing. The double-sided circuit board, the first stator, the second stator and a portion of the shaft are enclosed by the casing. Moreover, at least an end of the shaft is exposed outside the casing.

In an embodiment, the dual-impeller driving device further includes a casing, and a rotatable space of the first impeller and a rotatable space of the second impeller are separated from each other by the casing.

In an embodiment, the first stator and the first magnetic element are coaxial with each other with respect to the shaft. The first stator is arranged around the first magnetic element, or the first magnetic element is arranged around the first stator.

In an embodiment, the second stator and the second magnetic element are coaxial with each other with respect to the shaft. The second stator is arranged around the second magnetic element, or the second magnetic element is arranged around the second stator.

In accordance with another aspect of the present invention, there is provided a liquid-cooling heat dissipation device. The liquid-cooling heat dissipation device includes a liquid-cooling head, a liquid-cooling radiator, a communication pipe and a fluid channel. The communication pipe is connected with the liquid-cooling head and the liquid-cooling radiator. The fluid channel is a part of the communication pipe, or the fluid channel is disposed within the liquid-cooling head or disposed within the liquid-cooling radiator. The dual-impeller driving device includes a first impeller, a second impeller and a shaft. The first impeller is exposed outside the fluid channel. The second impeller is installed within the fluid channel. The first impeller and the second impeller are independently rotated about the shaft.

In an embodiment, the dual-impeller driving device further includes a double-sided circuit board, a first stator, a first magnetic element, a second stator and a second magnetic element. The double-sided circuit board has a first active surface and a second active surface. The first active surface and the second active surface are opposed to each other. The first stator is located beside the first active surface. The first magnetic element is located near the first stator, and combined with the first impeller. The second stator is located beside the second active surface. The second magnetic element is located near the second stator, and combined with the second impeller.

In an embodiment, the dual-impeller driving device further includes a casing, and the double-sided circuit board, the first stator and the second stator are enclosed by the casing.

In an embodiment, the dual-impeller driving device further includes a casing. The double-sided circuit board, the first stator, the second stator and a portion of the shaft are enclosed by the casing. Moreover, at least an end of the shaft is exposed outside the casing.

In an embodiment, the dual-impeller driving device further includes a casing, and a rotatable space of the first impeller and a rotatable space of the second impeller are separated from each other by the casing.

From the above descriptions, the present invention provides the dual-impeller driving device. Since the first impeller and the second impeller are coaxially driven, the volume of the dual-impeller driving device is reduced. Moreover, the first impeller and the second impeller are independently controlled. When the dual-impeller driving device is applied to the liquid-cooling heat dissipation device, the volume of the liquid-cooling heat dissipation device is reduced. Since the fan and the pump are independently operated, the operations of the two components are not interfered with and influenced by each other.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic cross-sectional view illustrating a dual-impeller driving device for a liquid-cooling heat dissipation device according to a first embodiment of the present invention;

FIG. 2 is a schematic cross-sectional view illustrating a dual-impeller driving device for a liquid-cooling heat dissipation device according to a second embodiment of the present invention;

FIG. 3 is a schematic cross-sectional view illustrating a dual-impeller driving device for a liquid-cooling heat dissipation device according to a third embodiment of the present invention;

FIG. 4 is a schematic cross-sectional view illustrating a dual-impeller driving device for a liquid-cooling heat dissipation device according to a fourth embodiment of the present invention; and

FIG. 5 is a schematic perspective view illustrating a liquid-cooling heat dissipation device with a dual-impeller driving device according to an embodiment of the present invention.

### DETAILED DESCRIPTION OF THE PREFERRED EMBODIMENT

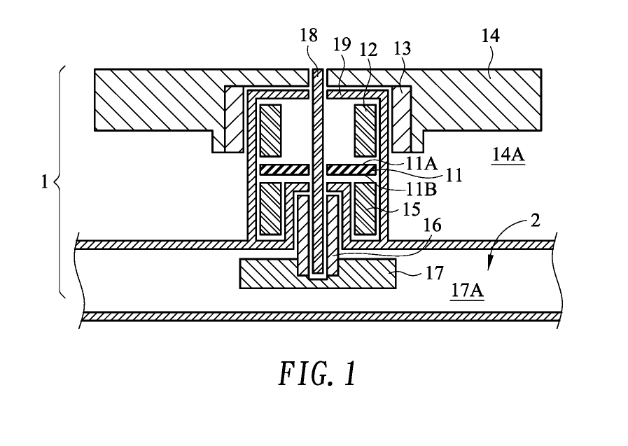

FIG. 1 is a schematic cross-sectional view illustrating a dual-impeller driving device for a liquid-cooling heat dissipation device according to a first embodiment of the present invention. The dual-impeller driving device 1 comprises a double-sided circuit board 11, a first stator 12, a first magnetic element 13, a first impeller 14, a second stator 15, a second magnetic element 16, a second impeller 17, a shaft 18 and a casing 19.

The double-sided circuit board 11 has a first active surface 11A and a second active surface 11B. The first active surface 11A and the second active surface 11B are opposed to each other. In this embodiment, the dual-impeller driving device uses the double-sided circuit board with two opposite active surfaces. In some other embodiments, the dual-impeller driving device uses two single-sided circuit boards to achieve the function of the double-sided circuit board, wherein the active surfaces of the two single-sided circuit boards are opposed to each other.

The first stator 12 is located beside the first active surface 11A. For example, the first stator 12 comprises a silicon steel plate or any other appropriate magnetic component. The first magnetic element 13 is a magnet. The first magnetic element 13 is located near the first stator 12. Moreover, the first magnetic element 13 and the first stator 12 are coaxial with each other with respect to the shaft 18. In the embodiment of FIG. 1, the first magnetic element 13 is arranged around the first stator 12. In some other embodiments, the first stator 12 is arranged around the first magnetic element 13.

The first impeller 14 is combined with the first magnetic element 13. The first active surface 11A of the double-sided circuit board 11, the first stator 12 and the first magnetic element 13 interact with each other to drive the rotation of the first impeller 14. In this embodiment, the first impeller 14 is used as a fan impeller for producing airflow.

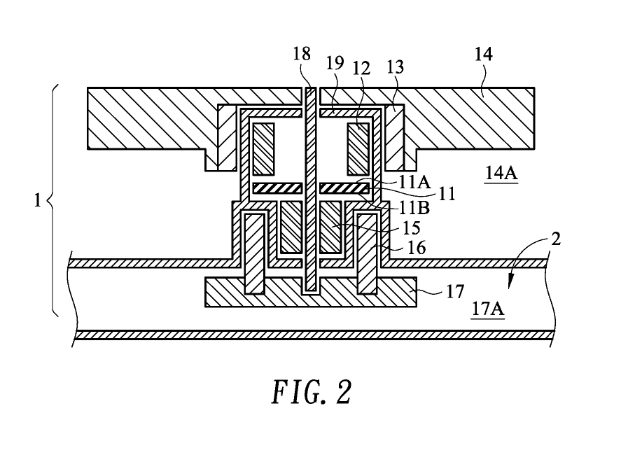

The second stator 15 is located beside the second active surface 11B. For example, the second stator 15 comprises a silicon steel plate or any other appropriate magnetic component. The second magnetic element 16 is a magnet. The second magnetic element 16 is located near the second stator 15. Moreover, the second magnetic element 16 and the second stator 15 are coaxial with each other with respect to the shaft 18. In the embodiment of FIG. 1, the second stator 15 is arranged around the second magnetic element 16. In some other embodiments, the second magnetic element 16 is arranged around the second stator 15 (see FIG. 2).

The second impeller 17 is combined with the second magnetic element 16. The second active surface 11B of the double-sided circuit board 11, the second stator 15 and the second magnetic element 16 interact with each other to drive the rotation of the second impeller 17. In this embodiment, the second impeller 17 is used as a water pump impeller for transporting a fluid (e.g., liquid). Consequently, the second impeller 17 can be installed or integrated in a fluid channel 2.

In accordance with the present invention, the shaft 18 is penetrated through the double-sided circuit board 11. Moreover, the first impeller 14 and the second impeller 17 are rotated about the centerline of the shaft 18. However, the rotation of the first impeller 14 and the rotation of the second impeller 17 are independent from each other. That is, the first impeller 14 and the second impeller 17 are not linked with each other, and the operation of the first impeller 14 and the operation of the second impeller 17 are not interfered with each other. For example, the dimensions, sizes, types or the driven objects (e.g., air or liquid) of the first impeller 14 and the second impeller 17 are possibly different. That is, the rotating speeds or torques of the first impeller 14 and the second impeller 17 are different. In case that the first impeller 14 and the second impeller 17 are independently controlled and operated, the functions of the first impeller 14 and the second impeller 17 can be normally provided and the use life and the stability of the dual-impeller driving device 1 are enhanced.

In the dual-impeller driving device 1 of this embodiment, the double-sided circuit board 11, the first stator 12, the second stator 15 and a portion of the shaft 18 are enclosed by the casing 19. Moreover, at least an end of the shaft 18 is exposed outside the casing 19. If the casing 19 is extended outside or the casing 19 is connected with the fluid channel 2, a rotatable space 14A of the first impeller 14 and a rotatable space 17A of the second impeller 17 are separated from each other by the casing 19. Optionally, a sealing ring or a sealing cover (not shown) is located at the junction between the shaft 18 and the casing 19 in order to achieve the sealing efficacy.

FIG. 2 is a schematic cross-sectional view illustrating a dual-impeller driving device for a liquid-cooling heat dissipation device according to a second embodiment of the present invention. The dual-impeller driving device 1 comprises a double-sided circuit board 11, a first stator 12, a first magnetic element 13, a first impeller 14, a second stator 15, a second magnetic element 16, a second impeller 17, a shaft 18 and a casing 19. The second stator 15 and the second magnetic element 16 are coaxial with each other with respect to the shaft 18. In comparison with the first embodiment, the second magnetic element 16 is arranged around the second stator 15. The second magnetic element 16 and the second impeller 17 are rotated about the centerline of the shaft 18. The structures and functions of the other components are identical to those of the first embodiment, and are not redundantly described herein.

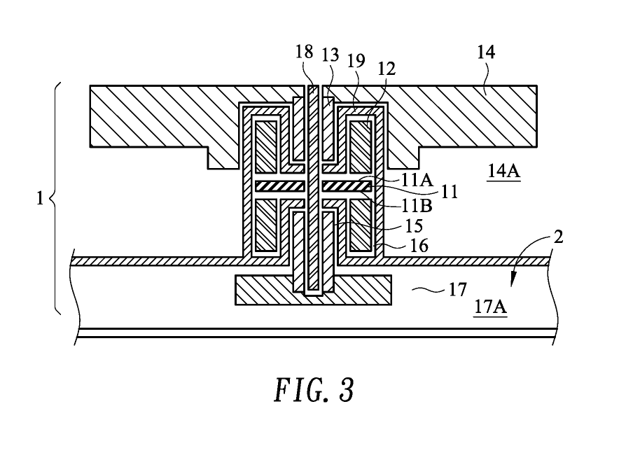

FIG. 3 is a schematic cross-sectional view illustrating a dual-impeller driving device for a liquid-cooling heat dissipation device according to a third embodiment of the present invention. The dual-impeller driving device 1 comprises a double-sided circuit board 11, a first stator 12, a first magnetic element 13, a first impeller 14, a second stator 15, a second magnetic element 16, a second impeller 17, a shaft 18 and a casing 19. The first magnetic element 13 and the first stator 12 are coaxial with each other with respect to the shaft 18. In comparison with the first embodiment, the first stator 12 is arranged around the first magnetic element 13. The first magnetic element 13 and the first impeller 14 are rotated about the centerline of the shaft 18. The structures and functions of the other components are identical to those of the first embodiment, and are not redundantly described herein.

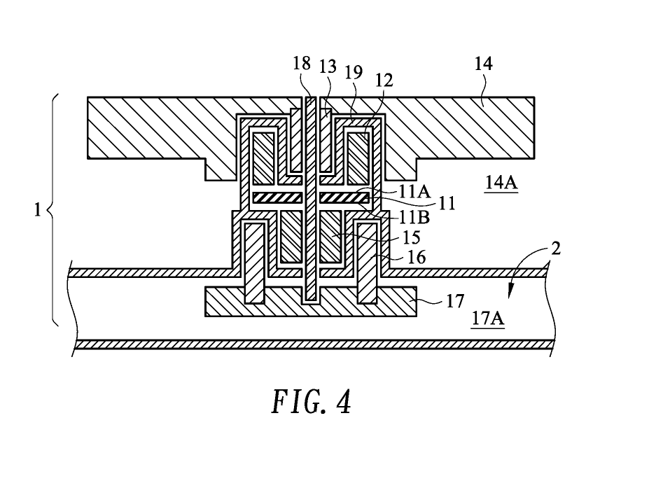

FIG. 4 is a schematic cross-sectional view illustrating a dual-impeller driving device for a liquid-cooling heat dissipation device according to a fourth embodiment of the present invention. The dual-impeller driving device 1 comprises a double-sided circuit board 11, a first stator 12, a first magnetic element 13, a first impeller 14, a second stator 15, a second magnetic element 16, a second impeller 17, a shaft 18 and a casing 19. The first magnetic element 13 and the first stator 12 are coaxial with each other with respect to the shaft 18. In comparison with the second embodiment, the first stator 12 is arranged around the first magnetic element 13. The first magnetic element 13 and the first impeller 14 are rotated about the centerline of the shaft 18. The structures and functions of the other components are identical to those of the second embodiment, and are not redundantly described herein.

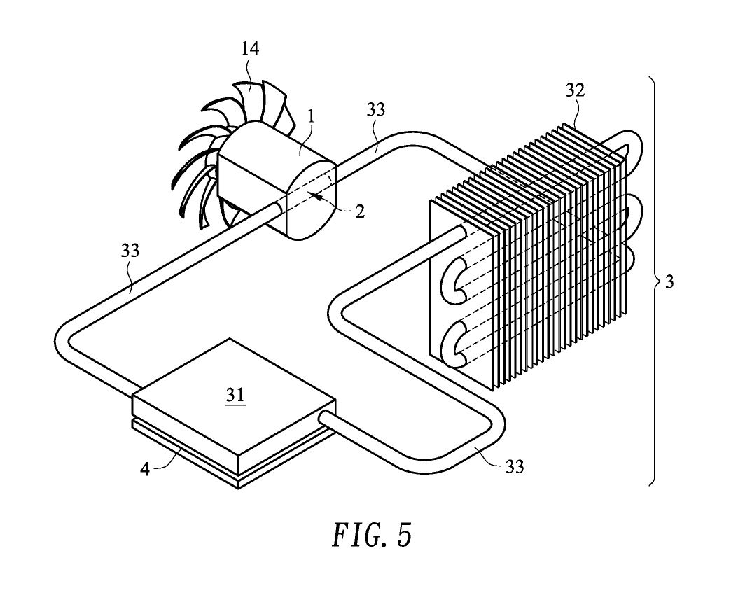

FIG. 5 is a schematic perspective view illustrating a liquid-cooling heat dissipation device with a dual-impeller driving device according to an embodiment of the present invention. The liquid-cooling heat dissipation device 3 comprises a liquid-cooling head 31, a liquid-cooling radiator 32, a communication pipe 33 and a fluid channel 2. The liquid-cooling head 31 and the liquid-cooling radiator 32 are connected with each other through the communication pipe 33. In addition, a working fluid is filled in the circular loop. After the heat from a heat source 4 is absorbed by the working fluid within the liquid-cooling head 31, the working fluid is transferred to the liquid-cooling radiator 32. Then, the temperature of the working fluid is decreased through plural fins of the liquid-cooling radiator 32 and the rotating first impeller 14 of the dual-impeller driving device 1. After the working fluid is cooled, the working fluid is returned back to the liquid-cooling head 31 by the rotating second impeller 17 of the dual-impeller driving device 1. Consequently, the working fluid can be circulated along a next loop. The second magnetic element and the second impeller (not shown) of the dual-impeller driving device 1 are installed within the fluid channel. When the dual-impeller driving device 1 is applied to the liquid-cooling heat dissipation device 3, the fluid channel 2 is formed as a part of the communication pipe 33 of the liquid-cooling heat dissipation device 3. Alternatively, in another embodiment, the fluid channel 2 is disposed within the liquid-cooling head 31 or disposed within the liquid-cooling radiator 32.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all modifications and similar structures.

What is claimed is:

1. A dual-impeller driving device, comprising:
a double-sided circuit board having a first active surface and a second active surface, wherein the first active surface and the second active surface are opposed to each other;
a first stator located beside the first active surface;
a first magnetic element located near the first stator;
a first impeller combined with the first magnetic element;
a second stator located beside the second active surface;
a second magnetic element located near the second stator;
a second impeller combined with the second magnetic element; and
a shaft penetrated through the double-sided circuit board, wherein the first impeller and the second impeller are rotated about the shaft.

2. The dual-impeller driving device according to claim 1, wherein the first active surface of the double-sided circuit board, the first stator and the first magnetic element interact with each other to drive a rotation of the first impeller, and the second active surface of the double-sided circuit board, the second stator and the second magnetic element interact with each other to drive a rotation of the second impeller.

3. The dual-impeller driving device according to claim 1, wherein a rotation of the first impeller and a rotation of the second impeller are independent from each other and not linked with each other.

4. The dual-impeller driving device according to claim 1, wherein the dual-impeller driving device further comprises a casing, and the double-sided circuit board, the first stator and the second stator are enclosed by the casing.

5. The dual-impeller driving device according to claim 1, wherein the dual-impeller driving device further comprises a casing, wherein the double-sided circuit board, the first stator, the second stator and a portion of the shaft are enclosed by the casing, and at least an end of the shaft is exposed outside the casing.

6. The dual-impeller driving device according to claim 1, wherein the dual-impeller driving device further comprises a casing, and a rotatable space of the first impeller and a rotatable space of the second impeller are separated from each other by the casing.

7. The dual-impeller driving device according to claim 1, wherein the first stator and the first magnetic element are coaxial with each other with respect to the shaft, wherein the first stator is arranged around the first magnetic element, or the first magnetic element is arranged around the first stator.

8. The dual-impeller driving device according to claim 1, wherein the second stator and the second magnetic element are coaxial with each other with respect to the shaft, wherein the second stator is arranged around the second magnetic element, or the second magnetic element is arranged around the second stator.

9. A liquid-cooling heat dissipation device, comprising:
a liquid-cooling head;
a liquid-cooling radiator;
a communication pipe connected with the liquid-cooling head and the liquid-cooling radiator;
a fluid channel, wherein the fluid channel is a part of the communication pipe, or the fluid channel is disposed within the liquid-cooling head or disposed within the liquid-cooling radiator; and
a dual-impeller driving device comprising a first impeller, a second impeller and a shaft, wherein the first impeller is exposed outside the fluid channel, the second impeller is installed within the fluid channel, and the first impeller and the second impeller are independently rotated about the shaft.

10. The liquid-cooling heat dissipation device according to claim 9, wherein the dual-impeller driving device further comprises:
a double-sided circuit board having a first active surface and a second active surface, wherein the first active surface and the second active surface are opposed to each other;
a first stator located beside the first active surface;
a first magnetic element located near the first stator, and combined with the first impeller;
a second stator located beside the second active surface; and
a second magnetic element located near the second stator, and combined with the second impeller.

11. The liquid-cooling heat dissipation device according to claim 10, wherein the dual-impeller driving device further comprises a casing, and the double-sided circuit board, the first stator and the second stator are enclosed by the casing.

12. The liquid-cooling heat dissipation device according to claim 10, wherein the dual-impeller driving device further comprises a casing, wherein the double-sided circuit board, the first stator, the second stator and a portion of the shaft are enclosed by the casing, and at least an end of the shaft is exposed outside the casing.

13. The liquid-cooling heat dissipation device according to claim 9, wherein the dual-impeller driving device further comprises a casing, and a rotatable space of the first impeller and a rotatable space of the second impeller are separated from each other by the casing.
